(19) United States
(12) Patent Application Publication
(10) Pub. No.: US 2007/0147638 A1
(43) Pub. Date: Jun. 28, 2007

(54) APPARATUS TO REMOVE A VOICE SIGNAL AND METHOD THEREOF

(76) Inventor: Han-gil MOON, Seoul (KR)

Correspondence Address: STANZIONE & KIM, LLP, 919 18TH STREET, N.W., SUITE 440, WASHINGTON, DC, 20006, US

(21) Appl. No.: 11/531,759

(22) Filed: Sep. 14, 2006

(30) Foreign Application Priority Data
Dec. 22, 2005 (KR) 2005-127782

(51) Int. Cl. H03G 5/00; H04R 3/00

(52) U.S. Cl. 381/98; 381/110

(57) ABSTRACT

An apparatus and a method of removing voice signals. The apparatus to remove a voice signal includes a band reject filter unit which generates a first signal by partially or wholly removing a plurality of predetermined frequency band components corresponding to a voice frequency band from an input signal, a sound quality compensation unit which generates a second signal by calculating a difference signal of channel signals of the first signal and removing a component corresponding to a predetermined intermediate frequency band, a band pass filter which generates a third signal by passing the predetermined intermediate frequency band of the first signal, and an audio signal generation unit which generates an output audio signal by synthesizing the second and third signals.

### CROSS-REFERENCE TO RELATED APPLICATIONS

This application claims the benefit of Korean Patent Application No. 10-2005-0127782, filed on Dec. 22, 2005, in the Korean Intellectual Property Office, the disclosure of which is incorporated herein in its entirety by reference.

### BACKGROUND OF THE INVENTION

1. Field of the Invention

The present general inventive concept relates to an audio apparatus, and more particularly, to an apparatus and a method of removing a voice signal.

2. Description of the Related Art

Generally, a stereo sound source is generated by down-mixing audio signals which are recorded on multi-tracks, for example, three or more tracks into a two-channel stereo signal. When the audio signal is recorded on the multi-tracks, different signals are recorded on the tracks. However, energy included in the signals of the tracks is superposed when the multi-track audio signals are down-mixed into the two-channel stereo signal. Accordingly, it is difficult to extract or remove a specific audio signal from the stereo signal into which an accompaniment signal and a voice signal are mixed in order to satisfy a listener's request.

FIG. 1 is a block diagram illustrating a conventional apparatus for removing a voice signal.

A discrete Fourier transformation unit 100 generates a frequency spectrum for each channel of input signals L and R by applying a discrete Fourier transform to the input signals L and R. A peak detection unit 120 detects one or more peaks which are common to the frequency spectrums for the channels of the input signals L and R. A peak removal unit 130 removes the one or more peaks which are detected by the peak detection unit 120 from the frequency spectrum of each channel. A synthesis unit 140 generates a frequency spectrum for each channel by synthesizing the frequency spectrum from which peaks are removed by the peak removal unit 130 and the frequency spectrum of the original input signals. An inverse discrete Fourier transformation unit 150 generates left and right signals L′ and R′ in a time domain by applying an inverse discrete Fourier Transform to the frequency spectrum for each channel.

However, since operations of the discrete Fourier transform and inverse discrete Fourier transform are needed, the conventional apparatus for removing a voice signal requires a large number of calculation operations. In addition, since other signals including tonal music signals, which have a common peak for the channels may be removed together with voice signals, the conventional apparatus for removing the voice signals has a distortion problem.

### SUMMARY OF THE INVENTION

The present general inventive concept provides a method of removing a voice signal to generate an audio signal having no distortion with simple arithmetic operations by using a signal in which a plurality of predetermined frequency band components corresponding to a voice frequency band are removed from an input signal.

The present general inventive concept also provides an apparatus to remove a voice signal.

Additional aspects of the present general inventive concept will be set forth in part in the description which follows and, in part, will be obvious from the description, or may be learned by practice of the general inventive concept.

The foregoing and/or other aspects of the present general inventive concept are achieved by providing an apparatus to remove a voice signal including a band reject filter unit which generates a first signal by partially or wholly removing a plurality of predetermined frequency band components corresponding to a voice frequency band from an input signal, a sound quality compensation unit which generates a second signal by calculating a difference signal of channel signals of the first signal and removing a component corresponding to a predetermined intermediate frequency band from the difference signal, a band pass filter which generates a third signal by filtering the predetermined intermediate frequency band of the first signal, and an audio signal generation unit which generates an output audio signal by synthesizing the second and third signals.

The band reject filter unit above may include a plurality of band reject filters to remove components of the input signal corresponding to formants, and the plurality of the band reject filters may have different central frequencies with respect to one another.

The central frequencies of the plurality of band reject filters included in the band reject filter unit may include at least two frequencies selected from 320 Hz, 500 Hz, 700 Hz, 1 kHz, 1.5 kHz, and 2.3 kHz.

The sound quality compensation unit may include a band reject filter to remove a component corresponding to the predetermined intermediate frequency band from the difference signal of the first signal.

The band reject filter of the sound quality compensation may remove components corresponding to frequency bands of 1 kHz to 4 kHz from the difference signal.

The sound quality compensation unit may further include an equalizer unit to control a magnitude of the second signal by applying a different gain to each frequency band of the second signal.

The band pass filter may perform filtering of components corresponding to frequency bands of 1 kHz to 4 kHz of the first signal.

The audio generation unit may generate a first channel audio signal using a difference signal between the second and third signals and generate a second channel audio signal using a sum signal of the second and third signals.

The foregoing and/or other aspects of the present general inventive concept are also achieved by providing a voice signal removing apparatus, including one or more filter units to receive an input audio signal and to remove voice frequency components from the audio signal, and a compensation unit to compensate the filtered audio signal for distortion induced by the one or more filter units.

The foregoing and/or other aspects of the present general inventive concept are also achieved by providing a voice signal removing apparatus, including a first filter to perform a first filtering operation on an input audio signal to generate a first audio signal, a second filter to perform a second filtering operation on the first audio signal to generate a third audio signal, a sound quality compensation unit to process a spectrum of the first audio signal to generate a second audio signal, and an audio generation unit to combine the second and third audio signals to generate an output audio signal.

The foregoing and/or other aspects of the present general inventive concept are also achieved by providing a method of removing a voice signal, the method including generating a first signal by partially or wholly removing a plurality of frequency band components corresponding to a voice frequency band from an input signal, generating a second signal by calculating a difference signal of channel signals of the first signal and removing a component corresponding to a predetermined intermediate frequency band from the difference signal, generating a third signal by filtering the predetermined intermediate frequency band of the first signal, and generating an output audio signal by synthesizing the second and third signals.

The generating of the first signal may include removing frequency bands corresponding to formants from the input signal.

The central frequencies may include at least two frequencies selected from 320 Hz, 500 Hz, 700 Hz, 1 kHz, 1.5 kHz, and 2.3 kHz.

The generating of the second signal may include removing components corresponding to frequency bands of 1 kHz to 4 kHz from the difference signal.

The generating of the second signal may further include controlling a magnitude of the second signal by applying a different gain to each frequency band of the second signal.

The generating of the third signal may include band-passing a component of a frequency band of 1 kHz to 4 kHz of the first signal.

The generating of the output audio signal may generate a first channel audio signal using a difference signal between the second and third signals and generating a second channel audio signal using a sum signal of the second and third signals.

The foregoing and/or other aspects of the present general inventive concept are also achieved by providing a voice signal removing method, including receiving an input audio signal in a time domain, filtering the audio signal to remove voice frequency components from the audio signal in the time domain, and compensating the filtered audio signal for distortion induced by the filtering of the audio signal in the time domain.

The foregoing and/or other aspects of the present general inventive concept are also achieved by providing a voice signal removing method, including performing a first filtering operation on an input audio signal to generate a first audio signal, performing a second filtering operation on the first audio signal to generate a third audio signal, processing a spectrum of the first audio signal to compensate for distortion in the first audio signal to generate a second audio signal, and combining the second and third audio signals to generate an output audio signal.

The foregoing and/or other aspects of the present general inventive concept are also achieved by providing a computer-readable medium having embodied thereon a computer program to perform the method(s) described above.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a block diagram illustrating a conventional apparatus for removing a voice signal;

FIG. 2A is a block diagram illustrating an apparatus to remove a voice signal according to an embodiment of the present general inventive concept;

FIG. 2B is a graph illustrating frequency characteristics of a band reject filter unit illustrated in FIG. 2A;

FIG. 3 is a detailed block diagram illustrating an apparatus to remove a voice signal according to another embodiment of the present general inventive concept;

FIG. 4 is a flowchart of a method of removing a voice signal according to an embodiment of the present general inventive concept; and

FIG. 5 is a detailed flowchart of the method illustrated in FIG. 4.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

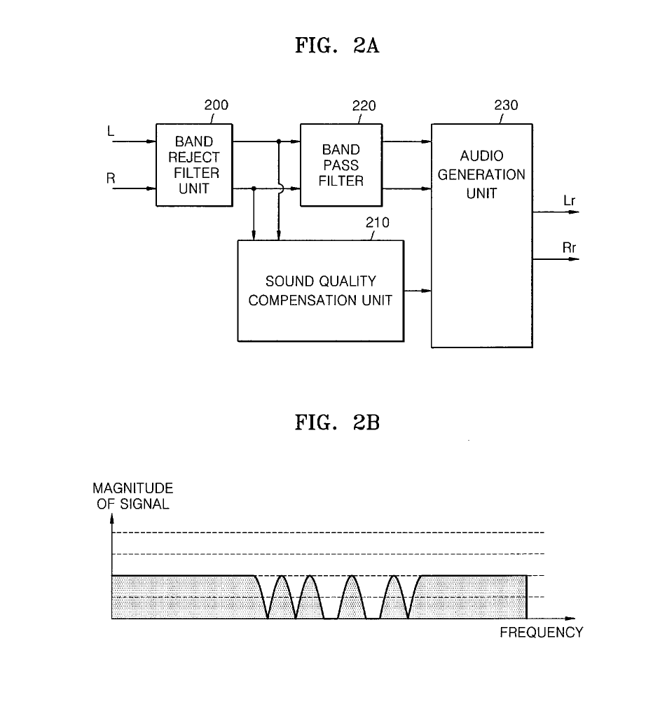

FIG. 2A is a block diagram illustrating an apparatus to remove a voice signal according to an embodiment of the present general inventive concept.

A band reject filter unit 200 generates a first signal by partially or wholly removing a plurality of predetermined frequency band components corresponding to a voice frequency band from an input signal.

A voice signal is a result of stressing specific harmonic sounds and suppressing other harmonic sounds by changing a magnitude and shape of an opening of one's mouth and moving one's tongue. In a waveform of the voice signal, there are a series of peaks and troughs, although a basic frequency of the voice signal does not change. Here, the peaks distributed in the waveform are called “formants.”

The band reject filter unit 200 may be configured to remove components corresponding to the formants from the input signal. The band reject filter unit 200 may include a plurality of band reject filters.

The band reject filter unit 200 may include the plurality of band reject filters to remove the components corresponding to the formants from the input signal, and the plurality of the band reject filters may have different central frequencies with respect to one another.

The central frequencies of the plurality of band reject filters included in the band reject filter unit 200 may include at least two frequencies selected from 320 Hz, 500 Hz, 700 Hz, 1 kHz, 1.5 kHz, and 2.3 kHz.

A sound quality compensation unit 210 calculates a difference signal of channel signals of the first signal, and removes components corresponding to a predetermined intermediate frequency band from the difference signal to generate a second signal. Components of some frequency bands causing a rough sound may be included in the difference signal calculated above. Such components cause deterioration in sound quality. Accordingly, the sound quality compensation unit 210 removes the components of the frequency bands causing the rough sounds.

The sound quality compensation unit 210 may include a band reject filter (not illustrated) to remove components corresponding to the predetermined intermediate frequency band from the difference signal of the first signal.

The band reject filter of the sound quality compensation unit 210 may remove components corresponding to frequency bands of 1 kHz to 4 kHz from the difference signal of the first signal.

The sound quality compensation unit 210 may further include an equalizer unit (not illustrated) to control a magnitude of the second signal by applying a different gain to each frequency band of the second signal.

A band pass filter 220 generates a third signal by filtering the predetermined intermediate frequency band of the first signal. The sound quality compensation unit 210 generates a second signal by using the signal in which the components causing the rough sound are removed from the difference signal of the first signal. As a result, a signal in which a specific frequency band component is removed can be obtained. Accordingly, unlike the sound quality compensation unit 210, the band pass filter 220 adjusts a frequency band balance of the second signal by comparatively amplifying components corresponding to the intermediate frequency band.

The band pass filter 220 may perform filtering of components corresponding to frequency bands of 1 kHz to 4 kHz of the first signal.

An audio generation unit 230 generates an output audio signal by synthesizing the second and third signals. In FIG. 2, Lr represents a signal of a left channel in which components corresponding to the voice frequency band are removed, and Rr represents a signal of a right channel in which components corresponding to the voice frequency band are removed.

The audio generation unit 230 can generate a first channel audio signal using a difference signal between the second and third signals and can generate a second channel audio signal using a sum signal of the second and third signals.

FIG. 2B is a graph illustrating frequency characteristics of the band reject filter unit 200 illustrated in FIG. 2. As illustrated in FIG. 2B, the band reject filter unit 200 removes or attenuates a plurality of predetermined frequency band components. It is possible to precisely remove voice signals by selectively removing frequency bands of voice signals as described above.

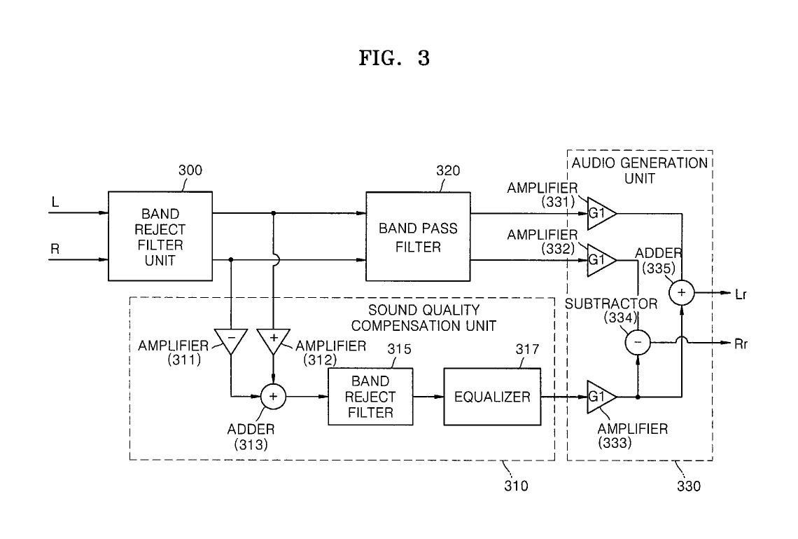

FIG. 3 is a detailed block diagram illustrating an apparatus to remove a voice signal according to an embodiment of the present general inventive concept. The voice signal removing apparatus of FIG. 3 may operate in a similar manner as the voice signal removing apparatus of FIG. 2A and/or may have similar components.

A band reject filter unit 300 generates first signals by partially removing a plurality of predetermined frequency band components corresponding to the voice frequency band from input signals.

The band reject filter 300 may be configured to remove components of frequency bands corresponding to formants. The band reject filter unit 300 may include a plurality of band reject filters.

Central frequencies of the plurality of the band reject filters may include at least two frequencies selected from 320 Hz, 500 Hz, 700 Hz, 1 kHz, 1.5 kHz, and 2.3 kHz. In other words, the band reject filter unit 300 may be configured to remove two or more components in the vicinity of 320 Hz, 500 Hz, 700 Hz, 1 kHz, 1.5 kHz, and 2.3 kHz frequency bands.

A sound quality compensation unit 310 generates a second signal by calculating a difference signal between the first signals for each channel, and removes components corresponding to a predetermined intermediate frequency band from the difference signal to generate a second signal. The calculation of the difference signal is performed by amplifiers 311 and 312 and an adder 313. As illustrated in FIG. 3, the sound quality compensation unit 310 includes a band reject filter 315 which removes components corresponding to the predetermined intermediate frequency band from the difference signal. The band reject filter 315 may remove components corresponding to frequency bands of 1 kHz and 4 kHz from the difference signal.

The sound quality compensation unit 310 may further include an equalizer unit 317 to control a magnitude of the second signal by applying different gains to the frequency bands of the second signal. The equalizer unit 317 enhances a spectrum shape which has been distorted by a series of filtering processes. In other words, the equalizer unit 317 amplifies components of lower frequency bands which have been attenuated comparatively and attenuates components of upper frequency bands which have been amplified comparatively.

A band pass filter 320 generates a third signal by filtering the predetermined intermediate frequency band of the first signal. The band pass filter 320 may perform filtering of a frequency band of 1 kHz to 4 kHz of the first signal.

An audio generation unit 330 generates an output audio signal by synthesizing the second and third signals. In FIG. 3, Lr represents a left channel signal in which components corresponding to a voice frequency band are removed, and Rr represents a right channel signal in which components corresponding to a voice frequency band are removed. The audio generation unit 330 generates an audio signal Rr of the first channel using a difference signal between the second signal and the right channel signal of the third signal and generates an audio signal Lr of the second channel using a sum signal of the second signal and the left channel signal of the third signal. The calculation of the difference signal between the second signal and the right channel signal of the third signal is performed by amplifiers 332 and 333 and a subtractor 334. The calculation of the sum signal between the second signal and the left channel signal of the third signal is performed by amplifiers 331 and 333 and an adder 335.

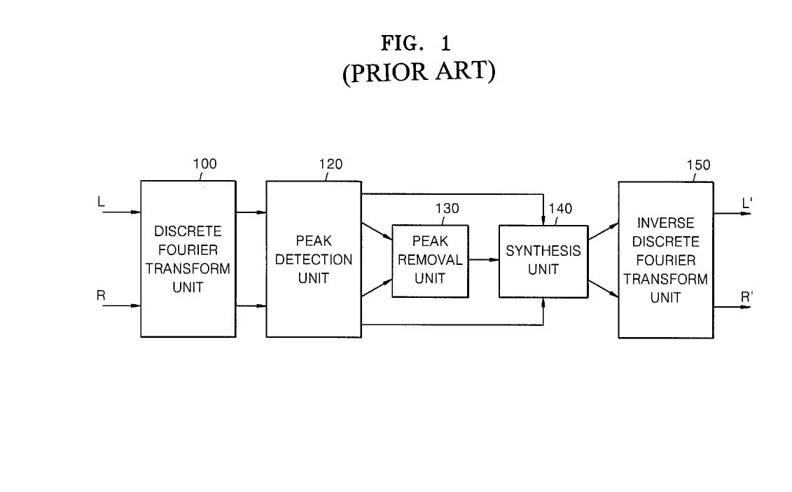

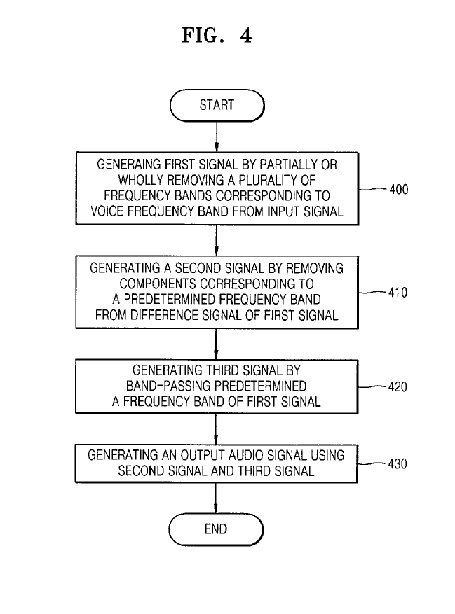

FIG. 4 is a flowchart illustrating a method of removing a voice signal according to an embodiment of the present general inventive concept. The method of FIG. 4 may be performed by the voice signal removing apparatus of FIG. 1 and/or the voice signal removing apparatus of FIG. 3. A first signal is generated by partially or wholly removing a plurality of frequency band components corresponding to a voice frequency band from an input signal (operation 400). The components of the plurality of the frequency bands corresponding to the voice frequency bands may be components corresponding to the formants described above.

The operation 400 of generating the first signal may include filtering with different central frequencies to remove components corresponding to the formants from the input signal.

A second signal is generated by calculating a difference signal of channel signals of the first signal and removing components corresponding to a predetermined intermediate frequency band from the difference signal (operation 410). Next, a third signal is generated by band-passing the predetermined intermediate frequency band of the first signal (operation 420). Finally, an output audio signal in which voice signals are removed is generated by synthesizing the second and third signals (operation 430).

The operation 410 of generating the second signal may include removing components corresponding to frequency bands of 1 kHz to 4 kHz from the difference signal of the first signal. The operation 410 of generating the second signal may further include controlling a magnitude of the second signal by applying a different gain to each frequency band of the second signal.

The operation 420 of generating the third signal may include filtering components of a frequency band of 1 kHz to 4 kHz of the first signal.

The operation 430 of generating the output audio signal may include generating a first channel audio signal using a difference signal between the second and third signals and generating a second channel audio signal using a sum signal of the second and third signals.

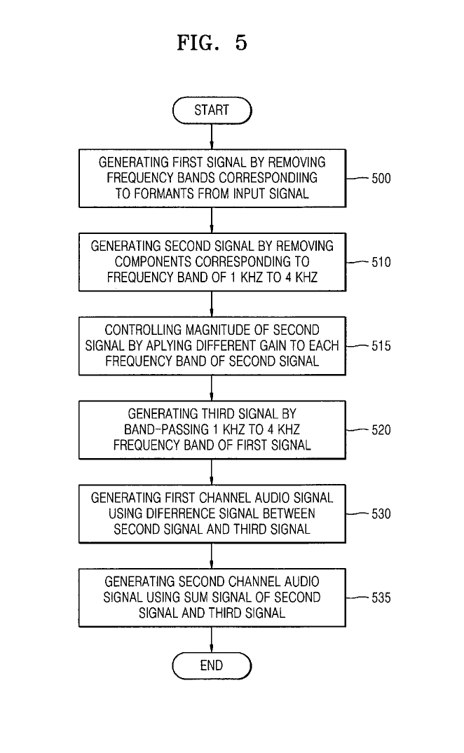

FIG. 5 is a detailed flowchart of the method of removing a voice signal of FIG. 4. The method of FIG. 4 may be performed by the voice signal removing apparatus of FIG. 1 and/or the voice signal removing apparatus of FIG. 3.

A first signal is generated by filtering a plurality of predetermined frequency band components corresponding to formants from an input signal (operation 500). The formants may include components in the vicinity of at least two frequency bands selected from 320 Hz, 500 Hz, 700 Hz, 1 kHz, 1.5 kHz, and 2.3 kHz.

A second signal is generated by calculating a difference signal of channel signals of the first signal and removing components corresponding to frequency bands of 1 kHz to 4 kHz (operation 510).

After the second signal is generated, a magnitude of the second signal is controlled by applying a different gain to each frequency band of the second signal (operation 515). The operation 515 enhances a shape of a spectrum which has been distorted by a series of filtering processes. In other words, by performing the operation 515, components of a lower frequency band which have been attenuated comparatively are amplified, and components of an upper frequency band which have been amplified comparatively are attenuated.

Next, a third signal is generated by band-passing components corresponding to frequency bands of 1 kHz to 4 kHz of the first signal (operation 520).

After the third signal is generated, an audio signal of a first channel is generated using a difference signal between the second and third signals (operation 530).

An audio signal of a second channel is generated using a sum signal of the second and third signals (operation 535).

The present general inventive concept may be embodied in a computer-readable medium having a computer program to perform the method of removing a voice signal according to embodiments of the present general inventive concept. When embodied as a software program, components of the present general inventive concept may be code segments that perform operations. The program or code segments may be stored on a processor-readable medium or may be transferred by a computer data signal combined with a carrier signal in a transfer medium or a communication network.

As described above, embodiments of the present general inventive concept do not require excessive arithmetic operations such as frequency transformation by partially or wholly removing components of a plurality of the predetermined frequency bands corresponding to a voice frequency band from an input signal and compensating a spectrum of a frequency band which has been distorted in filtering processes. Additionally, audio signals having no distortion can be generated by simple arithmetic operations in which voice signals are removed.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An apparatus to remove a voice signal, the apparatus comprising:
a band reject filter unit which generates a first signal by partially or wholly removing a plurality of predetermined frequency band components corresponding to a voice frequency band from an input signal;
a sound quality compensation unit which generates a second signal by calculating a difference signal of channel signals of the first signal and removing a component corresponding to a predetermined intermediate frequency band from the difference signal;
a band pass filter which generates a third signal by filtering the predetermined intermediate frequency band of the first signal; and
an audio signal generation unit which generates an output audio signal by synthesizing the second and third signals.

2. The apparatus of claim 1, wherein the band reject filter unit comprises:
a plurality of band reject filters to remove components of the input signal corresponding to formants; and
a plurality of the band reject filters having different central frequencies with respect to one another.

3. The apparatus of claim 2, wherein the central frequencies include at least two frequencies selected from 320 Hz, 500 Hz, 700 Hz, 1 kHz, 1.5 kHz, and 2.3 kHz.

4. The apparatus of claim 1, wherein the sound quality compensation unit comprises a band reject filter to remove components corresponding to the predetermined intermediate frequency band from the difference signal of the first signal.

5. The apparatus of claim 4, wherein the band reject filter removes components corresponding to frequency bands of 1 kHz to 4 kHz from the difference signal.

6. The apparatus of claim 1, wherein the sound quality compensation unit comprises an equalizer unit to control a magnitude of the second signal by applying a different gain to each frequency band of the second signal.

7. The apparatus of claim 1, wherein the band pass filter performs filtering of components corresponding to frequency bands of 1 kHz to 4 kHz of the first signal.

8. The apparatus of claim 1, wherein the audio generation unit generates a first channel audio signal using a difference signal between the second and third signals and generates a second channel audio signal using a sum signal of the second and third signals.

9. A voice signal removing apparatus, comprising:
one or more filter units to receive an input audio signal and to remove voice frequency components from the audio signal; and
a compensation unit to compensate the filtered audio signal for distortion induced by the one or more filter units.

10. The voice signal removing apparatus of claim 9, wherein the one or more filter units filter the input audio signal in a time domain, and the compensation unit compensates the filtered audio signal in the time domain.

11. The voice signal removing apparatus of claim 9, further comprising:
an audio generating unit to combine output signals of the one or more filter units and the compensation unit to generate an output audio signal.

12. The voice signal removing apparatus of claim 11, wherein the one or more filter units comprise:
a band reject filter unit to remove at least one component of the audio signal corresponding to at least one formant; and
a band pass filter to pass a predetermined band of the filtered audio signal.

13. The voice signal removing apparatus of claim 12, wherein the compensation unit removes the predetermined band of the input audio signal such that the audio generating unit combines an output of the compensation unit and the passed predetermined band of the filtered audio signal.

14. The voice signal removing apparatus of claim 9, wherein the compensation unit comprises an equalizer to equalize a spectrum of the audio signal.

15. The voice signal removing apparatus of claim 9, wherein the one or more filter units and the compensation unit are arranged in parallel with respect to one another.

16. A voice signal removing apparatus, comprising:
a first filter to perform a first filtering operation on an input audio signal to generate a first audio signal;
a second filter to perform a second filtering operation on the first audio signal to generate a third audio signal;
a sound quality compensation unit to process a spectrum of the first audio signal to generate a second audio signal; and
an audio generation unit to combine the second and third audio signals to generate an output audio signal.

17. The voice signal removing apparatus of claim 16, wherein the audio generation unit comprises:
an adder to add a left channel signal of the third audio signal with the second audio signal to generate an output left channel signal; and
a subtractor to subtract a right channel signal of the third audio signal from the second audio signal to generate an output right channel signal.

18. A method of removing a voice signal, the method comprising:
generating a first signal by partially or wholly removing a plurality of frequency band components corresponding to a voice frequency band from an input signal;
generating a second signal by calculating a difference signal of channel signals of the first signal and removing a component corresponding to a predetermined intermediate frequency band from the difference signal;
generating a third signal by band-passing a predetermined intermediate frequency band of the first signal; and
generating an output audio signal by synthesizing the second and third signals.

19. The method of claim 18, wherein the generating of the first signal comprises removing components having different central frequencies corresponding to formants from the input signal.

20. The method of claim 19, wherein the central frequencies include at least two frequencies selected from 320 Hz, 500 Hz, 700 Hz, 1 kHz, 1.5 kHz, and 2.3 kHz.

21. The method of claim 18, wherein the generating of the second signal comprises removing components corresponding to frequency bands of 1 kHz to 4 kHz from the difference signal.

22. The method of claim 18, wherein the generating of the second signal comprises controlling a magnitude of the second signal by applying a different gain to each frequency band of the second signal.

23. The method of claim 18, wherein the generating of the third signal comprises band-passing components of a frequency band of 1 kHz to 4 kHz of the first signal.

24. The method of claim 18, wherein the generating of the output audio signal comprises:
generating a first channel audio signal using a difference signal between the second and third signals; and
generating a second channel audio signal using a sum signal of the second and third signals.

25. A voice signal removing method, comprising:
receiving an input audio signal in a time domain;
filtering the audio signal to remove voice frequency components from the audio signal in the time domain; and
compensating the filtered audio signal for distortion induced by the filtering of the audio signal in the time domain.

26. A voice signal removing method, comprising:
performing a first filtering operation on an input audio signal to generate a first audio signal;
performing a second filtering operation on the first audio signal to generate a third audio signal;
processing a spectrum of the first audio signal to compensate for distortion in the first audio signal to generate a second audio signal; and
combining the second and third audio signals to generate an output audio signal.

27. A computer-readable medium containing executable code to perform a method of removing a voice signal, the medium comprising:
executable code to generate a first signal by partially or wholly removing a plurality of frequency band components corresponding to a voice frequency band from an input signal;
executable code to generate a second signal by calculating a difference signal of channel signals of the first signal and removing a component corresponding to a predetermined intermediate frequency band from the difference signal;
executable code to generate a third signal by band-passing a predetermined intermediate frequency band of the first signal; and
executable code to generate an output audio signal by synthesizing the second and third signals.
